(19) United States
(12) Patent Application Publication
(10) Pub. No.: US 2004/0188685 A1
(43) Pub. Date: Sep. 30, 2004

(54) Thin film transistor and fabrication method thereof

(75) Inventors: Chiung-Wei Lin, Taipei (TW); Yung-Hui Yeh, Hsinchu (TW)

Correspondence Address: QUINTERO LAW OFFICE, 1617 BROADWAY, 3RD FLOOR, SANTA MONICA, CA, 90404, US

(73) Assignee: Industrial Technology Research Institute

(21) Appl. No.: 10/439,442

(22) Filed: May 16, 2003

(30) Foreign Application Priority Data
Mar. 31, 2003 (TW) 92107246

(51) Int. Cl. H01L 29/76

(52) U.S. Cl. 257/66

(57) ABSTRACT

A TFT with a microcrystalline film. The channel is composed by a microcrystalline silicon layer and an amorphous silicon layer. The microcrystalline silicon layer is disposed near the gate electrode as the first channel layer, providing a current flow path in a horizontal orientation. The amorphous silicon layer is disposed away from the gate electrode as the second channel layer, providing a current flow path in a vertical orientation. Accordingly, the driving current of the transistor can be elevated due to the high conductivity of the microcrystalline silicon layer. Moreover, unnecessary current occurring when the transistor is switched off is reduced due to the high resistance of the amorphous silicon layer.

### BACKGROUND OF THE INVENTION

1. Field of the Invention

The present invention relates to a thin film transistor, and in particular to a thin film transistor with a microcrystalline layer and fabrication method thereof.

2. Description of the Related Art

Thin film transistors (TFTS) drive pixels in active matrix type liquid crystal display devices, active matrix type organic light-emitting display device, image sensors and the like. Generally, the TFTs used in these apparatuses are formed from silicon semiconductor thin film. Such silicon semiconductor thin films are roughly classified into two types: amorphous silicon (a-Si) semiconductor and crystalline silicon semiconductor films.

Of these two types, the amorphous silicon semiconductor film is preferred and enjoys general use because of its low processing temperature and ease of manufacture by vapor deposition, thus lending itself well to mass production. Compared to the crystalline silicon semiconductor film, however, the amorphous silicon semiconductor film is inferior in properties such as electrical conductivity.

TFTs with polysilicon film have higher electric field effect mobility than those with conventional amorphous silicon film, and therefore, the TFT can be operated at a high speed. Thus, the pixel control which has been conducted at a driver circuit outside of the substrate may be conducted at the driver circuit formed on the same substrate as the pixel. The following three methods are known for the production of crystalline silicon semiconductors.

The first method forms a crystalline silicon semiconductor film directly in a film deposition step. The second method forms amorphous semiconductor film followed by laser radiation to crystallize the amorphous silicon film by the laser's optical energy. The third method forms an amorphous semiconductor film followed by application of heat energy to crystallize the amorphous silicon film.

However, the three methods above have the following disadvantages. In the first method, since the crystallization proceeds during the deposition step, a thick silicon film must be formed to obtain a crystalline silicon film of large grain size. Consequently, it is technically difficult to form a film having good semiconductor properties uniformly over the entire surface of the substrate. Furthermore, the crystalline silicon film is usually deposited at a temperature at least as high as 600° C.

The second method utilizes crystallization in the melting and solidification processes, and allows the formation of a high-quality silicon film with a small grain size yet having properly treated grain boundaries. However, with the lasers commonly used, the processing throughput is low because the effective laser beam radiation area is small. A further disadvantage is that the stability of lasers is not sufficient to uniformly process over the entire surface of a large substrate.

The third method is limited to unstable laser beams. The uniformity of the polysilicon thin film transistor formed by laser crystallization is low. Crystal grains spread parallel to the substrate surface and crystals having a grain size of a few micrometers may be formed. During this crystal growth process, grain boundaries are formed with the growing crystal grains in collision with one another, resulting in grain boundaries having lattice defects. Consequently, the grain boundaries act as carrier traps, resulting in current leakage.

### SUMMARY OF THE INVENTION

Accordingly, the present invention implements a uniform polysilicon process at low temperature to provide a thin film transistor with the high driving current with which conventional amorphous thin film transistors lack, and lower leakage than conventional polysilicon thin film transistors.

To achieve the object, the present invention provides a thin film transistor including a gate electrode, a gate insulating layer, a microcrystalline semiconductor layer, an amorphous semiconductor layer, source/drain, and source/drain electrodes. The gate insulating layer is formed on the gate electrode. The microcrystalline semiconductor layer is formed over the gate insulating layer. The amorphous semiconductor layer is formed over the microcrystalline semiconductor layer. The source/drain regions are formed on the amorphous semiconductor layer and on opposite sides of the gate electrode respectively, and the source/drain electrodes are deposited on the source and drain regions respectively.

Preferably, the microcrystalline semiconductor layer is a microcrystalline silicon layer and the amorphous semiconductor layer is an amorphous silicon layer. The source/drain regions are a doped semiconductor layer. The patterns of the microcrystalline semiconductor layer and the amorphous semiconductor layer are identical.

Accordingly, the driving current of the transistor can be elevated due to the high conductivity of the microcrystalline semiconductor layer. Moreover, unnecessary current occurring when the transistor is switched off can be reduced due to the high resistance of the amorphous semiconductor layer.

Another thin film transistor is further provided according to the invention, and includes a gate electrode, a gate insulating layer, a channel layer, a high resistance layer, source/drain, and source/drain electrodes. The gate insulating layer is formed on the gate electrode. The channel layer is formed over the gate insulating layer. The high resistance layer is formed over the channel layer. The source/drain regions are formed on the high resistance layer and on opposite sides of the gate electrode respectively, and the source/drain electrodes are deposited on the source and drain regions respectively.

Preferably, the channel layer is a microcrystalline silicon layer and the high resistance layer is an amorphous silicon layer. The source/drain regions are a doped semiconductor layer. The patterns of the channel layer and the high resistance layer are identical.

Accordingly, the driving current of the transistor can be elevated due to the high conductivity of the microcrystalline semiconductor layer. Moreover, unnecessary current occurring when the transistor is switched off can be reduced due to the high resistance of the high resistance layer.

Still another thin film transistor is further provided according to the invention, and includes a gate electrode, a gate insulating layer, a first channel layer, a second channel layer, source/drain, and source/drain electrodes. The gate insulating layer is formed on the gate electrode. The source/drain regions are formed on the second channel layer and on opposite sides of the gate electrode respectively, and the source/drain electrodes are deposited on the source and drain regions respectively. The first channel layer is formed over the gate insulating layer to provide a current flow path parallel to the surface of the gate electrode. The second channel layer is formed over the first channel layer to provide a current flow path perpendicular to the surface of the gate electrode.

Preferably, the first channel layer is a microcrystalline silicon layer and the second channel layer is an amorphous silicon layer. The source/drain regions are a doped semiconductor layer. The patterns of the first channel layer and the second channel layer are identical.

The three thin film transistors disclosed above can be implemented on organic light emitting display devices or display devices incorporating thin film transistors thereon. The driving current of the transistor can be elevated due to the high conductivity of the microcrystalline semiconductor layer. Moreover, unnecessary current occurring when the transistor is switched off can be reduced due to the high resistance of the high resistance layer, preferably for current-driven display devices.

The present invention further provides a method for thin film transistor fabrication. A gate electrode is formed on a substrate. A gate insulating layer is subsequently formed over the gate electrode and the substrate. A microcrystalline semiconductor layer, an amorphous semiconductor layer and a doped semiconductor layer are formed over the gate insulating layer subsequently. The doped semiconductor layer, the amorphous semiconductor layer, and the microcrystalline semiconductor layer are then defined to form a active area. A metal layer is formed over the doped semiconductor layer. The metal layer and the doped semiconductor layer are defined to form source/drain regions on the doped semiconductor layer and source/drain electrodes on the metal layer.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIGS. 1A to 1D are cross sections illustrating the fabricating flow of a thin film transistor according to the invention;

FIG. 2 is an equivalent circuit diagram of an organic light emitting display device driven by two TFTs according to the invention; and

FIG. 3 is a cross section of a part of an organic light emitting display device with an organic light emitting diode and a driving transistor T₂ according to the invention.

### DETAILED DESCRIPTION OF THE INVENTION

### Structure of a Thin Film Transistor

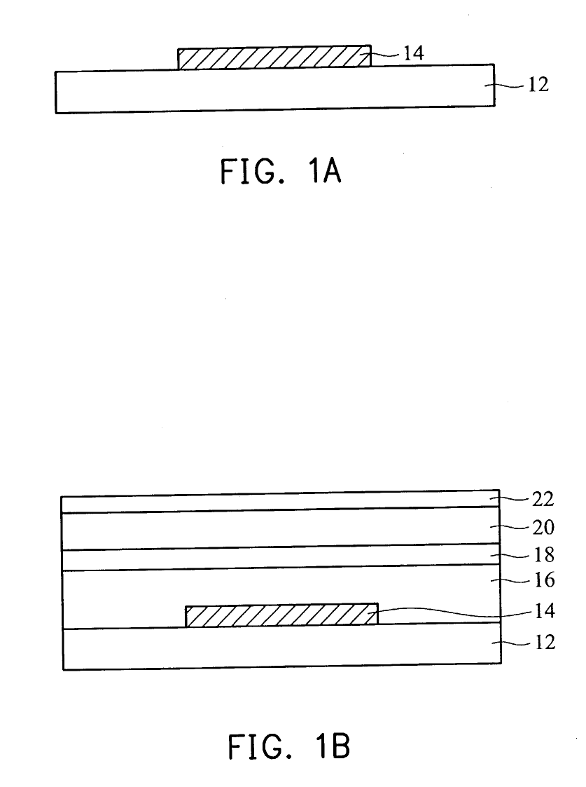

FIG. 1D shows a cross section of a thin film transistor according to the invention. A gate electrode 14 is disposed on a substrate 12, which can be aluminum (Al), aluminum alloy, or molybdenum (Mo).

A gate insulating layer 16a is deposited over the gate electrode 14 and the substrate 12. The preferred insulating material is silicon oxide, silicon nitride, or oxynitride (SiON).

A microcrystalline semiconductor layer is formed over the gate insulating layer 16a as the first channel layer 18a. An amorphous semiconductor layer is subsequently deposited over the microcrystalline semiconductor layer 18a as the second channel layer 20a. In the thin film transistor, the resistance of the first channel layer 18a is lower than the second channel layer 20a, which makes the second channel layer 20a a higher resistance layer. Preferably, the microcrystalline semiconductor layer 18a is a microcrystalline silicon layer and the amorphous semiconductor layer 20a an amorphous silicon layer.

In one preferred embodiment, the pattern of the microcrystalline semiconductor layer 18a can be identical to the pattern of the amorphous semiconductor layer 20a. Although the patterns are identical, the current flow will not be affected by resistance differences. In addition, the part without current flow of the amorphous semiconductor layer 20a can be a passivation layer of the first channel layer 18a. In another embodiment, the pattern of a part of the amorphous semiconductor layer 20a is identical to the pattern of a part of the microcrystalline semiconductor layer 18a.

Source region 22S and drain region 22D are formed on the amorphous semiconductor layer 20a and on the opposite sides of the gate electrode 14. A source electrode 24S and a drain electrode 24D are disposed on the source 22S and the drain 22D respectively. The source region 22S and the source electrode 24S are identical in pattern, as are the drain region 22D and the drain electrode 24D.

Since the resistance of the amorphous semiconductor layer 20a is higher than the resistance of the above source/drain 22S/22D and the microcrystalline semiconductor layer 18a below, the current on the amorphous semiconductor layer 20a takes the shortest path between the source 22S and the microcrystalline semiconductor layer 18a and between the drain 22D and the microcrystalline semiconductor layer 18a when an operating voltage is applied to the thin film transistor for activation. Consequently, the microcrystalline semiconductor layer 18a provides a current flow path parallel to the surface of the gate electrode 14, and the amorphous semiconductor layer 20a provides a current flow path perpendicular to the surface of the gate electrode 14 (the current flow path is as the Label I in the FIGS.).

Accordingly, the driving current is elevated due to the high conductivity of the microcrystalline semiconductor layer 18a. Moreover, unnecessary current occurring when the transistor is switched off can be reduced due to the high resistance of the amorphous semiconductor layer.

### The Fabrication Process of a Thin Film Transistor

FIGS. 1A to 1D are cross sections illustrating the fabricating flow of a thin film transistor according to the invention

In FIG. 1A, a first conductive layer is formed on a substrate 12 and defined as a gate electrode 14. Preferably, the substrate 12 is a glass substrate or a flexible substrate, such as a plastic substrate.

In FIG. 1B, a insulating layer 16, a microcrystalline semiconductor layer 18, an amorphous semiconductor layer 20, and a doped semiconductor layer 22 are formed subsequently over the gate electrode 14. Preferably, the insulating layer 16 is a silicon oxide layer, a silicon nitride layer, or an oxy nitride layer formed by deposition with a thickness of about 3000 Å. The microcrystalline semiconductor layer 18 is preferably a microcrystalline silicon layer with a thickness of 100 to 300 Å formed by chemical vapor deposition at about 250° C. The amorphous semiconductor layer 20 is preferably an amorphous silicon layer with a thickness of 1100 Å formed by chemical vapor deposition at about 250° C. The doped semiconductor layer 22 can be an amorphous silicon layer or a microcrystalline silicon layer with a thickness of about 500 Å and the dopants can be n-type or P-type, depending on the transistor.

The doped semiconductor layer 22, the amorphous semiconductor layer 20, the microcrystalline semiconductor layer 18, and the insulating 16 are further defined to form an active area composed of 22a, 20a, 18a and 16a, as shown in FIG. 1C.

In FIG. 1d, a second conductive layer is formed over the doped semiconductor layer 22a. The second conductive layer and the doped semiconductor layer 22a are defined to form a source electrode 24S, a drain electrode 24D of the second conductive layer, and a source region 22S and a drain region 22D of the doped semiconductor layer 22a.

Preferably, the exposed amorphous semiconductor layer 20a is also etched anisotropically during definition of the source and drain 22S and 22D.

The thin film transistor formed accordingly is constructed like a perpendicular type of lightly doped drain structure, and thus, the reliability of the transistor is increased.

### TFT Transistor Implementation

Further is described implementation of the above thin film transistors on an organic light emitting display (OLED) device. The present invention is not limited to OLED, however, but also applies to other display devices which incorporate thin film transistors.

An organic light emitting display (OLED) device is a self-luminous display device that does not require backlighting, providing the advantages of rapid response, high brightness and wide viewing angle. The organic light emitting display (OLED) devices can be classified into active and passive OLEDs. The active OLED is driven by current, in which each pixel consists of at least one switch TFT to control the image data access and address thereof. Another driving TFT is required for an active OLED to modulate the current based on the voltage stored in a capacitor and the brightness and grey scale are adjusted accordingly. The active OLED can be driven by two TFTs or four TFTS.

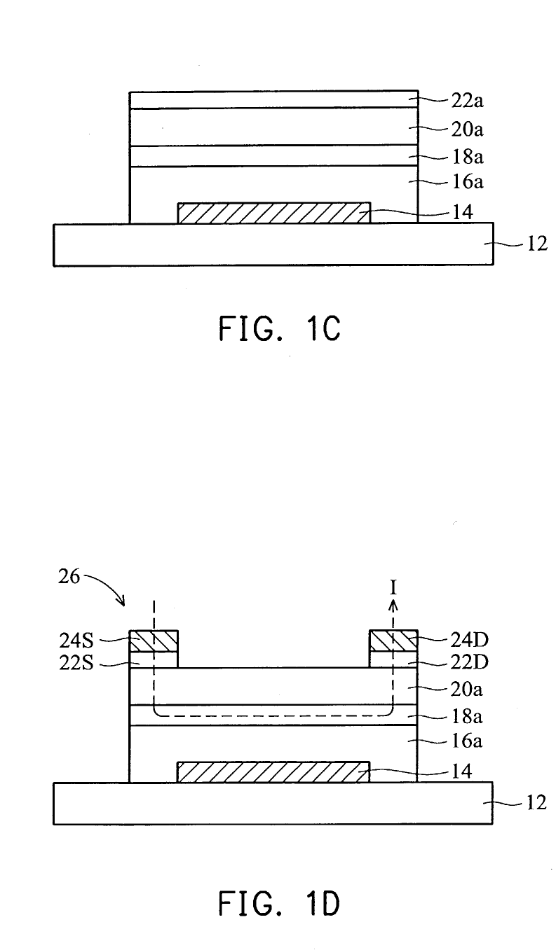

FIG. 2 is an equivalent circuit diagram of an organic light emitting display device driven by two TFTs according to the invention.

A pixel A on an organic light emitting display comprises a switch TFT T₁, a storage capacitor Cs, a driving TFT T₂ and an organic light emitting diode OLED. A gate of the switch TFT T₁ is coupled to a scanning signal line SCAN and a drain of the switch TFT T₁ is coupled to a data line DATA. One side of the storage capacitor Cs is coupled to the drain region of the TFT T₁ with the other side coupled to a reference voltage level VL. A gate of the driving TFT T₂ is coupled to the drain region of the switch TFT T₁ and a source of the driving TFT T₂ is coupled to a power supply V_{DD}. Moreover, the anode of the organic light emitting diode OLED is coupled to the drain region of the driving TFT T₂ with the cathode is coupled to the grounding GDN.

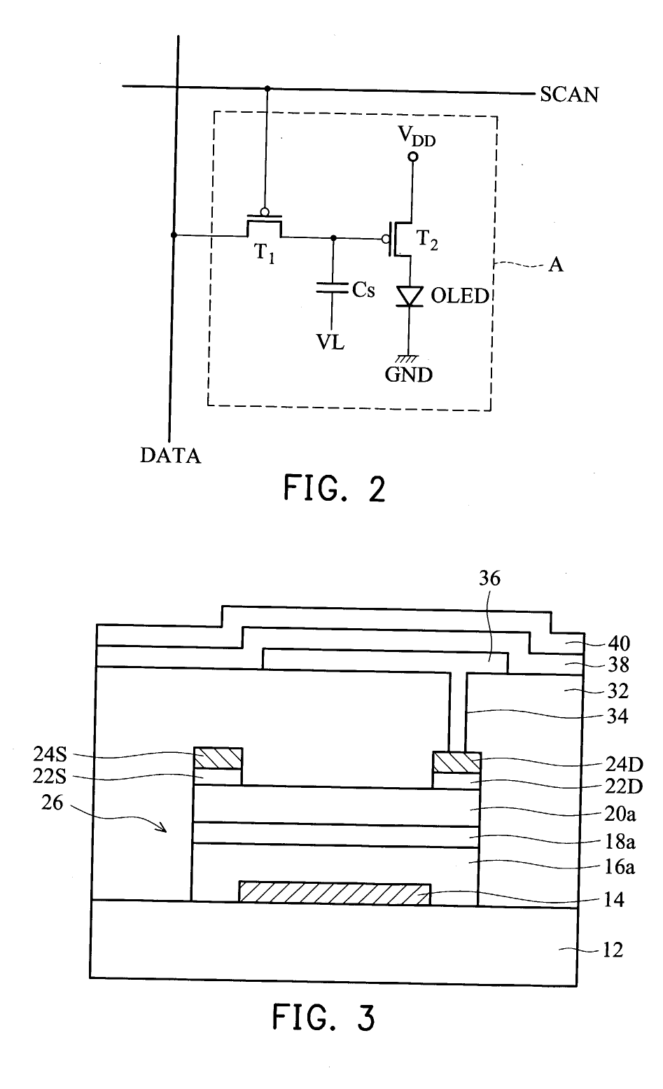

FIG. 3 is a cross section of a part of an organic light emitting display device with an organic light emitting diode OLED and a driving transistor T₂ according to the invention.

As shown in FIG. 3, after forming a TFT 26 on the substrate 12, a insulating layer 32 is disposed on the TFT 26, preferably polyamide or acrylic resin. In one embodiment, an JSR Japan synthetic resin number PC 403, a transparent and heat-resistant insulating material, is used. A contact hole 34 is formed subsequently on the insulating layer 32 exposing the drain electrode 24D.

A conductive layer is deposited over the insulating layer 32 and fills the contact 34 to connect the drain electrode 24D. The conductive layer can be indium tin oxide (ITO), indium zinc oxide (IZO), aluminum zinc oxide (AZO) or zinc oxide (ZnO) formed by sputtering, electron beam evaporation, thermal coating, or chemical vapor deposition. The conductive layer is further defined to form a pixel electrode 36 and an anode, connecting with the drain electrode 24D. The conductive layer can be defined by lithography and anisotropic etching.

A light emitting layer 38 is formed over the insulating layer 32 as an anode 36. The light emitting layer 38 can be small molecular organic light emitting material or an organic light emitting polymer. A small molecular organic light emitting layer can be formed by vacuum evaporation. An organic light emitting polymer layer can be formed by spin coating, ink-jet printing, or screen printing.

A cathode layer 40 is formed on the anode 36, which can be Cu, Ag, Mg, Al, metals with low work function, or alloys thereof formed by vacuum evaporation or sputtering.

An organic light emitting diode is achieved accordingly.

The present invention implements the well-know amorphous silicon process in company with microcrystalline process to elevate the driving current for an OLED display device and reduce unnecessary current occurring when the OLED is switched off.

The thin film transistor formed according to the present invention is constructed like a perpendicular lightly doped drain structure. The channel is composed of the amorphous and microcrystalline semiconductor layers. The amorphous semiconductor layer provides a current flow path in a vertical orientation and the microcrystalline semiconductor layers provides a current flow path in a horizontal orientation.

The driving capability of the TFT according to the invention is superior to the amorphous TFT. The driving voltage of a conventional amorphous TFT is about 4.5 V with a mobility of 0.75 cm²/Vsec, and the driving voltage of the TFT according to the invention is about 2.5 V with a mobility of 4.3 cm²/Vsec.

The on/off ratio of the TFT according to the invention (10^{7.5}) is higher than the conventional amorphous TFT (10⁶).

Moreover, the operational consistency of the TFT according to the invention is also superior to the conventional amorphous TFT.

In addition, the microcrystalline semiconductor layer in the TFT according to the invention can be formed by low temperature deposition process, which can be incorporated with other sub-process to form TFTs on a flexible substrate, such as a plastic substrate, that is usually heat irresistible.

Furthermore, the cost for the TFT according to the invention is lower than conventional low temperature polysilicon TFT process.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art) Therefore, the scope of the appended claims should be accorded the broadest interpretation so as to encompass all such modifications and similar arrangements.

What is claimed is:

1. A thin film transistor, comprising:
a gate electrode;
a gate insulating layer over the gate electrode;
a microcrystalline semiconductor layer over the gate insulating layer;
an amorphous semiconductor layer over the microcrystalline semiconductor layer;
a source region and a drain region formed on the amorphous semiconductor layer and on opposite sides of the gate electrode respectively; and
a source electrode and a drain electrode deposited on the source and drain regions respectively.

2. The thin film transistor as claimed in claim 1, wherein patterns of the microcrystalline semiconductor layer and the amorphous semiconductor layer are identical.

3. The thin film transistor as claimed in claim 1, wherein the pattern of the amorphous semiconductor layer is identical to the patterns of the source and drain regions.

4. The thin film transistor as claimed in claim 1, wherein the pattern of a part of the amorphous semiconductor layer is identical to the pattern of the source and drain regions and the pattern of another part of the amorphous semiconductor layer is identical to the microcrystalline semiconductor layer.

5. The thin film transistor as claimed in claim 1, wherein the microcrystalline semiconductor layer comprises microcrystalline silicon and the amorphous semiconductor layer comprises amorphous silicon.

6. The thin film transistor as claimed in claim 1, wherein the source and drain regions comprise doped semiconductor layers.

7. The thin film transistor as claimed in claim 6, wherein the source and drain regions comprises a doped amorphous silicon layer or a doped microcrystalline silicon layer.

8. The thin film transistor as claimed in claim 1, wherein the drain electrode is coupled to an organic light emitting diode.

9. A thin film transistor, comprising:
a gate electrode;
a gate insulating layer over the gate electrode;
a channel layer over the gate insulating layer;
a high resistance layer over the channel layer;
a source region and a drain region formed on the high resistance layer and on opposite sides of the gate electrode respectively; and
a source electrode and a drain electrode deposited on the source and drain regions respectively.

10. The thin film transistor as claimed in claim 9, wherein the pattern of the channel layer is identical to the pattern of the high resistance layer.

11. The thin film transistor as claimed in claim 9, wherein the pattern of the high resistance layer is identical to the pattern of the source and drain regions.

12. The thin film transistor as claimed in claim 9, wherein the pattern of a part of the high resistance layer is identical to the pattern of the source and drain regions and the pattern of another part of the high resistance layer is identical to the pattern of the channel layer.

13. The thin film transistor as claimed in claim 9, wherein the channel layer comprises microcrystalline silicon and the high resistance layer comprises amorphous silicon.

14. The thin film transistor as claimed in claim 9, wherein the source and drain regions comprise a doped semiconductor layer.

15. The thin film transistor as claimed in claim 14, wherein the source and drain regions are a doped amorphous silicon layer or a doped microcrystalline silicon layer.

16. The thin film transistor as claimed in claim 9, wherein the drain electrode is coupled to an organic light emitting diode.

17. A thin film transistor, comprising:
a gate electrode;
a gate insulating layer over the gate electrode;
a first channel layer over the gate insulating layer to provide a current flow path parallel to the surface of the gate electrode;
a second channel layer over the first channel layer to provide a current flow path perpendicular to the surface of the gate electrode;
a source region and a drain region formed on the second channel layer and on opposite sides of the gate electrode respectively; and
a source electrode and a drain electrode deposited on the source and drain regions respectively.

18. The thin film transistor as claimed in claim 17, wherein the patterns of the first channel layer and the second channel layer are identical.

19. The thin film transistor as claimed in claim 17, wherein the pattern of the second channel layer is identical to the pattern of the source and drain regions.

20. The thin film transistor as claimed in claim 17, wherein the pattern of a part of the second channel layer is identical to the pattern of the source and drain regions and the pattern of another part of the second channel layer is identical to the pattern of the first channel layer.

21. The thin film transistor as claimed in claim 17, wherein the first channel layer comprises microcrystalline silicon and the second channel layer comprises amorphous silicon.

22. The thin film transistor as claimed in claim 17, wherein the source and drain regions comprise a doped semiconductor layer.

23. The thin film transistor as claimed in claim 22, wherein the source and drain regions comprise a doped amorphous silicon layer or a doped microcrystalline silicon layer.

24. The thin film transistor as claimed in claim 17, wherein the drain electrode is coupled to an organic emitting diode.

25. A method of fabricating a thin film transistor, comprising the steps of:
providing a substrate;
forming a gate electrode on the substrate;
forming a gate insulating layer over the gate electrode and the substrate;
forming a microcrystalline semiconductor layer over the gate insulating layer;
forming an amorphous semiconductor layer over the microcrystalline semiconductor layer;
forming a doped semiconductor layer over the amorphous semiconductor layer;
defining the doped semiconductor layer, the amorphous semiconductor layer, and the microcrystalline semiconductor layer to form a active area;
forming a metal layer over the doped semiconductor layer; and
defining the metal layer and the doped semiconductor layer to form a source region and a drain region on the doped semiconductor layer and a source electrode and a drain electrode on the metal layer.

26. The method as claimed in claim 25, wherein the substrate is a glass substrate or a flexible substrate.

27. The method as claimed in claim 26, wherein the substrate is a glass substrate or a flexible substrate.

28. The method as claimed in claim 25, wherein the doped semiconductor layer is a doped amorphous silicon layer or a doped microcrystalline silicon layer.

29. The method as claimed in claim 25, wherein the amorphous semiconductor layer comprises amorphous silicon and the microcrystalline semiconductor layer comprises microcrystalline silicon.

30. The method as claimed in claim 29, wherein the amorphous semiconductor layer is formed by chemical vapor deposition at about 250° C.

31. The method as claimed in claim 29, wherein the microcrystalline semiconductor layer is formed by chemical vapor deposition at about 250° C.

32. The method as claimed in claim 25, wherein the amorphous semiconductor layer is defined simultaneously while defining the metal layer and the doped semiconductor layer.

33. The method as claimed in claim 25, wherein an upper portion of the amorphous semiconductor layer is defined simultaneously while defining the metal layer and the doped semiconductor layer.

34. The method as claimed in claim 25, wherein the drain electrode is coupled to an organic light emitting diode.

35. The method as claimed in claim 34, wherein the organic light emitting diode is fabricated by the steps of:
forming an insulating layer over the thin film transistor composed by the gate electrode, the gate insulating layer, the microcrystalline semiconductor layer, the amorphous semiconductor layer, the source region, the drain region, the source electrode and the drain electrode;
forming a contact on the insulating layer exposing the drain electrode;
forming a pixel electrode on the insulating layer to connect with the drain electrode via the contact;
forming a light emitting layer on the pixel electrode and the insulating layer; and
forming a cathode layer on the light emitting layer.

36. The method as claimed in claim 35, wherein the pixel electrode comprises ITO, IZO, AZO or ZnO.

37. The method as claimed in claim 35, wherein the light emitting layer comprises small molecular organic light emitting material or an organic light emitting polymer for a diode.

38. The method as claimed in claim 35, wherein the cathode layer comprises Cu, Ag, Mg, Al, metals with low work function, or alloys thereof.
